(19) United States
(12) Patent Application Publication
(10) Pub. No.: US 2024/0334745 A1
(43) Pub. Date: Oct. 3, 2024

(54) DISPLAY DEVICE

(71) Applicant: Samsung Display Co., LTD., Yongin-si (KR)

(72) Inventors: DONG-HOON LEE, Yongin-si (KR); JANGMI KANG, Yongin-si (KR); HAEMIN KIM, Yongin-si (KR); YOUNGWAN SEO, Yongin-si (KR); GEUNHO LEE, Yongin-si (KR)

(21) Appl. No.: 18/436,977

(22) Filed: Feb. 8, 2024

(30) Foreign Application Priority Data
Mar. 29, 2023 (KR) 10-2023-0041457

(51) Int. Cl. H10K 59/122; H10K 59/131

(52) U.S. Cl. CPC H10K 59/122; H10K 59/131

(57) ABSTRACT

A display device includes a substrate including a display area, and a peripheral area surrounding the display area in plan view, a power line on the substrate, and overlapping the peripheral area, a pixel electrode on the substrate, overlapping the display area, and spaced apart from the power line, a light-emitting layer on the pixel electrode, and overlapping the display area, a common electrode on the light-emitting layer, and overlapping the display area, and a partition wall on the substrate, overlapping the display area and the peripheral area, directly contacting the common electrode in the display area, and directly contacting the power line in the peripheral area.

### CROSS-REFERENCE TO RELATED APPLICATION

The present application claims priority to, and the benefit of, Korean Patent Application No. 10-2023-0041457, filed on Mar. 29, 2023, in the Korean Intellectual Property Office (KIPO), the entire disclosure of which is incorporated herein by reference.

### BACKGROUND

### 1. Field

Embodiments relate to a display device that provides visual information.

### 2. Description of the Related Art

A display device is a device that displays an image to provide visual information to a user. The display device may be a flat panel display device, such as a liquid crystal display, a field emission display, or a light-emitting display. The light-emitting display device may include an organic light-emitting display device including an organic light-emitting diode element as a light-emitting element, an inorganic light-emitting display device including an inorganic semiconductor element as a light-emitting element, or a subminiature light-emitting diode device (or micro light-emitting diode device) including a micro light-emitting device as a light-emitting device on a subminiature light-emitting diode element (or micro light-emitting diode element).

The display device may include a power line for transmitting a panel-driving voltage to a peripheral area. To transfer the panel-driving voltage to the display area, a power line and a common electrode may be electrically connected to each other through a partition wall including titanium and aluminum.

### SUMMARY

Embodiments provide a display device with improved reliability.

A display device according to embodiments of the present disclosure includes a substrate including a display area, and a peripheral area surrounding the display area in plan view, a power line on the substrate, and overlapping the peripheral area, a pixel electrode on the substrate, overlapping the display area, and spaced apart from the power line, a light-emitting layer on the pixel electrode, and overlapping the display area, a common electrode on the light-emitting layer, and overlapping the display area, and a partition wall on the substrate, overlapping the display area and the peripheral area, directly contacting the common electrode in the display area, and directly contacting the power line in the peripheral area.

The partition wall may contact a side surface of the common electrode.

The display device may further include a pixel-defining layer on the substrate, under the partition wall, and exposing a part of the pixel electrode, and an insulating layer between the substrate and the pixel-defining layer.

The insulating layer may define a first opening partially overlapping the power line in the peripheral area, wherein the pixel-defining layer defines a second opening overlapping the first opening.

The first opening and the second opening overlap the partition wall.

The power line may include a first part in which holes are defined, and overlapping the pixel-defining layer and the insulating layer, and a second part in which the holes are not defined, and directly contacting the partition wall through the first opening and the second opening.

The pixel-defining layer may include an inorganic material.

The insulating layer may include an organic material.

The partition wall may include a first partition layer on the pixel-defining layer, and a second partition layer on the first partition layer.

The first partition layer and the second partition layer may include different respective materials.

The first partition layer may include aluminum, wherein the second partition layer includes titanium.

The partition wall may extend from the display area to the peripheral area.

A display device according to embodiments of the present disclosure includes a substrate including a display area, and a peripheral area surrounding the display area in plan view, a power line on the substrate, and overlapping the peripheral area, a pixel electrode on the substrate, overlapping the display area and the peripheral area, and defining a contact opening overlapping the power line, a light-emitting layer on the pixel electrode, and overlapping the display area, a common electrode on the light-emitting layer, and overlapping the display area, and a partition wall on the pixel electrode, overlapping the display area and the peripheral area, directly contacting the common electrode in the display area, and directly contacting the power line through the contact opening in the peripheral area.

The partition wall may contact a side surface of the common electrode.

The display device may further include a pixel-defining layer on the pixel electrode, under the partition wall, and exposing a part of the pixel electrode in the display area, and an insulating layer between the substrate and the pixel electrode.

The insulating layer may define a first opening overlapping the contact opening, wherein the pixel-defining layer defines a second opening overlapping the first opening.

The contact opening, the second opening, and the second opening may overlap the partition wall.

The power line may include a first part in which holes are defined, and a second part in which the holes are not defined, wherein the first part overlaps the pixel-defining layer, the pixel electrode, and the insulating layer, and wherein the second part directly contacts the partition wall through the contact opening, the first opening, and the second opening.

The partition wall may include a first partition layer on the pixel-defining layer, and a second partition layer on the first partition layer, and including a material that is different from that of the first partition layer.

The first partition layer may include aluminum, wherein the second partition layer includes titanium.

In a display device according to embodiments, because a pixel electrode is spaced apart from a power line, the power line and a partition wall may directly contact each other. Accordingly, resistance can be reduced because the partition wall directly contacts the power line in the peripheral area and directly contacts the common electrode in the display area. In addition, because the pixel electrode is not located between the power line and the partition wall, the outgassing amount and parasitic capacitance can be reduced. Accordingly, reliability of the display device can be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is an enlarged view illustrating an enlarged area A of FIG. 1.

FIG. 3 is a cross-sectional view taken along the line I-I′ of FIG. 2.

FIGS. 4, 5, 6, and 7 are layout views illustrating parts of a display device according to one or more embodiments of the present disclosure.

FIG. 8 is a cross-sectional view taken along the line II-II′ of FIG. 7.

FIGS. 9, 10, and 11 are layout views illustrating a part of a display device according to one or more other embodiments of the present disclosure.

FIG. 12 is a cross-sectional view taken along the line III-III′ of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

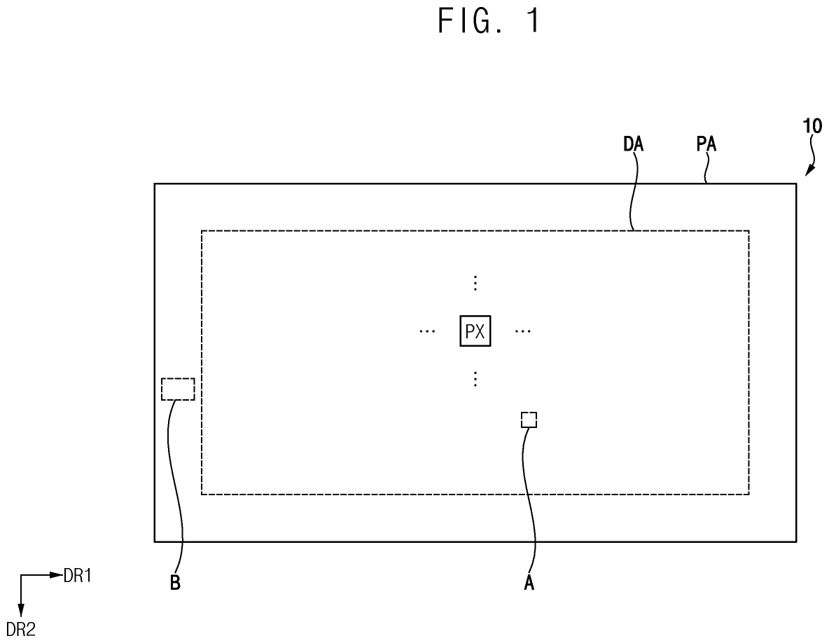

FIG. 1 is a plan view illustrating a display device according to one or more embodiments of the present disclosure.

Referring to FIG. 1, a display device 10 according to one or more embodiments may include a display area DA and a peripheral area PA.

The display device 10 may have a rectangular planar shape having a long side in a first direction DR1 and a short side in a second direction DR2. The second direction DR2 may cross the first direction DR1. However, it is not limited thereto.

The display area DA may be an area for displaying an image. The planar shape of the display area DA may be a rectangular shape, or may be a rectangular shape with rounded corners. However, the planar shape of the display area DA is not limited thereto, and the display area DA may have various planar shapes, such as a circular shape, an elliptical shape, a polygonal shape, or the like.

The peripheral area PA may be located around the display area DA. The peripheral area PA may surround the display area DA (e.g., in plan view). The peripheral area PA may be an area not displaying an image. In one or more embodiments, drivers for displaying an image of the display area DA may be located in the peripheral area PA.

Pixels PX may be arranged in a matrix in the display area DA. The pixels PX may be defined as a minimum light-emitting unit capable of displaying white light. In addition, signal lines, such as a gate line and a data line, may be located in the display area DA. The signal lines, such as the gate line and the data line, may be connected to each of the pixels PX. Each of the pixels PX may receive a gate signal, a data signal, or the like from the signal line.

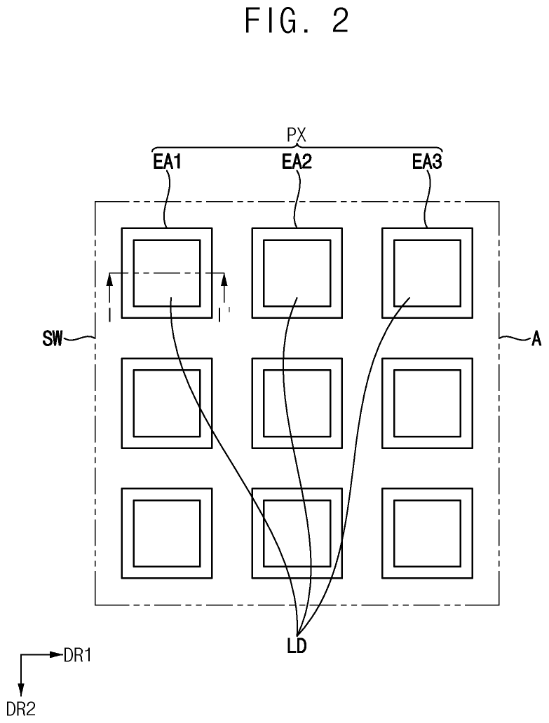

In one or more embodiments, the display device 10 may be a subminiature light-emitting diode display device (or micro light-emitting diode display device) including a subminiature light-emitting diode (or micro light-emitting diode) as a light-emitting element. However, the present disclosure is not limited thereto. FIG. 2 is an enlarged view illustrating an enlarged area A of FIG. 1.

Further referring to FIG. 2, each of the plurality of pixels PX may include a plurality of light-emitting areas EA1, EA2, and EA3 that emit light. In the drawings, it is illustrated that each of the plurality of pixels PX includes three light-emitting areas EA1, EA2, and EA3, but the present disclosure is not limited thereto. For example, each of the plurality of pixels PX may include four or more light-emitting areas.

Each of the plurality of light-emitting areas EA1, EA2, and EA3 may include a light-emitting diode LD that emits a first light. The first light may be white light. However, the present disclosure is not limited thereto. In addition, although the light-emitting diode LD has a rectangular planar shape, the present disclosure is not limited thereto. For example, the light-emitting diode LD may have a polygonal shape other than a quadrangular shape, or may have a circular shape, an elliptical shape, or an atypical shape.

Each of the first light-emitting areas EA1 may emit second light. Each of the first light-emitting areas EA1 may convert the first light emitted from the light-emitting diode LD into second light to emit the second light. For example, the second light may be light in a blue wavelength band. However, the embodiments of the present disclosure are not limited thereto.

Each of the second light-emitting areas EA2 may emit third light. Each of the second light-emitting areas EA2 may convert the first light emitted from the light-emitting diode LD into the third light to emit the third light. The third light may be light in a green wavelength band. However, the present disclosure is not limited thereto.

Each of the third light-emitting areas EA3 may emit fourth light. Each of the third light-emitting regions EA2 may convert the first light emitted from the light-emitting diode LD into the fourth light to emit the fourth light. The fourth light may be light in a red wavelength band. However, the present disclosure is not limited thereto.

The first light-emitting areas EA1, the second light-emitting areas EA2, and the third light-emitting areas EA3 may be alternately arranged in the first direction DR1. For example, the first light-emitting areas EA1, the second light-emitting areas EA2, and the third light-emitting areas EA3 may be arranged in the order of the first light-emitting area EA1, the second light-emitting area EA2, and the third light-emitting area EA3 in the first direction DR1.

The first light-emitting areas EA1 may be arranged in the second direction DR2. The second light-emitting areas EA2 may be arranged in the second direction DR2. The third light-emitting areas EA3 may be arranged in the second direction DR2.

The plurality of light-emitting areas EA1, EA2, and EA3 may be partitioned by the partition wall SW. The partition wall SW may surround the light-emitting diode LD. The partition wall SW may be spaced apart from the light-emitting diode LD. The partition wall SW may have a planar shape of a mesh shape, a net shape, or a lattice shape.

Each of the plurality of light-emitting areas EA1, EA2, and EA3 defined by the partition wall SW may have a rectangular planar shape, but the present disclosure is not limited thereto. For example, each of the plurality of light-emitting areas EA1, EA2, and EA3 defined by the partition wall SW may have a polygonal shape other than a quadrangular shape, or may have a circular shape, an elliptical shape, or an atypical shape.

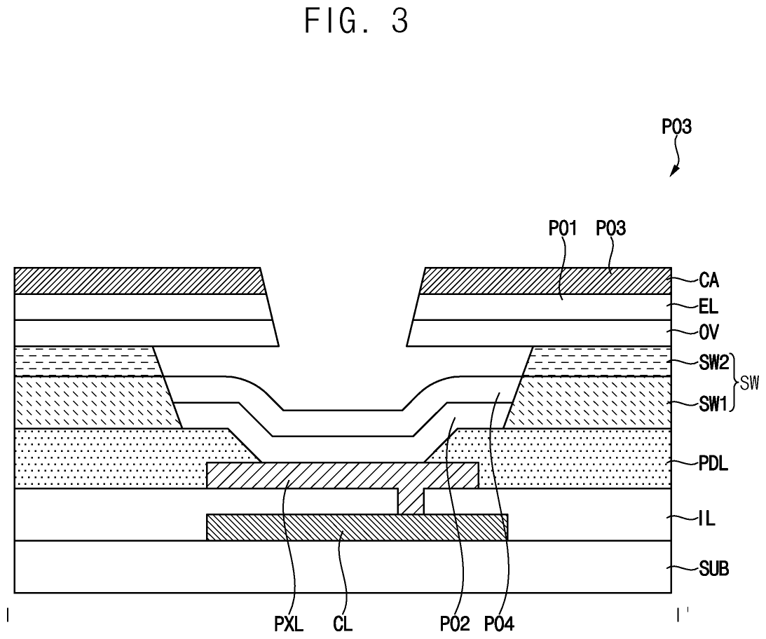

FIG. 3 is a cross-sectional view taken along the line I-I′ of FIG. 2.

FIGS. 1, 2, and 3, the display device 10 may include a substrate SUB, a conductive layer CL, an insulating layer IL, a pixel electrode PXL, a pixel-defining layer PDL, a partition wall SW, an overhang layer pattern OV, an organic material layer EL, and a second electrode CA.

As the display device 10 includes the display area DA and the peripheral area PA, the substrate SUB may include the display area DA and the peripheral area PA. The substrate SUB may include various materials. For example, the substrate SUB may include various materials, such as silicon wafer, glass, plastic, or the like.

The conductive layer CL may be located on the substrate SUB. The conductive layer CL may include a conductive material. For example, the conductive layer CL may include a metal, such as titanium, aluminum, or the like. However, the present disclosure is not limited thereto.

The insulating layer IL may be located on the substrate SUB. The insulating layer IL may cover the conductive layer CL. The insulating layer IL may include an organic material.

Additional conductive layers and insulating layers may be further located between the substrate SUB and the conductive layer CL. However, the present disclosure is not limited thereto.

The pixel electrode PXL may be located on the substrate SUB. The pixel electrode PXL may overlap the display area DA. In addition, the pixel electrode PXL may not overlap the peripheral area PA. The pixel electrode PXL may include a conductive material. For example, the pixel electrode PXL may include indium tin oxide (ITO), indium zinc oxide (IZO), zinc oxide (ZnOₓ), indium oxide (InOₓ), or the like. These may be used alone or in combination with each other.

The pixel electrode PXL may have a single-layer structure including at least one of the above materials. Alternatively, the pixel electrode PXL may have a multilayer structure.

The pixel-defining layer PDL may be located on the substrate SUB, and may define an opening exposing a part of an upper surface of the pixel electrode PXL.

The pixel-defining layer PDL may include an inorganic material. For example, the pixel definition layer PDL may include silicon nitride (SiNₓ), silicon oxide (SiOₓ), silicon oxynitride (SiₓN_{y}O_{z}), magnesium fluoride (MgFₓ), or the like.

In one or more embodiments, the partition wall SW may be located on the pixel-defining layer PDL. The partition wall SW may overlap the display area DA and the peripheral area PA. That is, the partition wall SW may extend from the display area DA to the peripheral area PA.

In one or more embodiments, the partition wall SW may include a first partition layer SW1 and a second partition layer SW2. The first partition layer SW1 may be located on the pixel-defining layer PDL. The second partition layer SW2 may be located on the first partition layer SW1.

In one or more embodiments, the first partition layer SW1 and the second partition layer SW2 may include different materials. For example, the first partition layer SW1 may include a first metal, and the second partition layer SW2 may include a second metal that is different from the first metal. For example, the first metal may be aluminum (AI), and the second metal may be titanium (Ti). In other words, when the first partition layer SW1 includes aluminum, the second partition layer SW2 including titanium may be located on the first partition layer SW1. Accordingly, the second partition layer SW2 may protect the first partition layer SW1 from corrosion.

In one or more embodiments, the first partition layer SW1 and the second partition layer SW2 may have the same taper angle. For example, each of the first partition layer SW1 and the second partition layer SW2 may have a regular tapered shape. However, the present disclosure is not limited thereto. For example, the second partition layer SW2 may be omitted.

The overhang layer pattern OV may be located on the partition wall SW. For example, the overhang layer pattern OV may be located on the second partition layer SW2. The overhang layer pattern OV may include an inorganic material or a metal. For example, the overhang layer pattern OV may include an inorganic material. Examples of the inorganic material may include silicon nitride (SiNₓ), silicon oxide (SiOₓ), or the like. For another example, the overhang layer pattern OV may include metal. Examples of the metal may include titanium (Ti) or the like.

A width of an upper surface of the overhang layer pattern OV may be greater than a width of an upper surface of the pixel-defining layer PDL. Accordingly, the overhang layer pattern OV may serve as a tip.

The organic material layer EL may overlap the display area DA. The organic material layer EL may include a first light-emitting part PO1, and a second light-emitting part PO2 spaced apart from the first light-emitting part PO1. The first light-emitting part PO1 may be located on the overhang layer pattern OV. The second light-emitting part PO2 may be located on the pixel electrode PXL and the pixel-defining layer PDL. In other words, the first light-emitting part PO1 of the organic material layer EL and the second light-emitting part PO2 of the organic material layer EL may have a disconnected structure.

The organic material layer EL may include a light-emitting layer and a functional layer. The light-emitting layer may overlap the display area DA. The functional layer may include a hole transport layer, a hole injection layer, an electron transport layer, an electron injection layer, or the like. For example, the organic material layer EL may include a hole transport layer, a hole injection layer, an emission layer, an electron transport layer, and an electron injection layer. However, the present disclosure is not limited thereto, and the stacking order or stacking shape may be changed.

The common electrode CA may overlap the display area DA. The common electrode CA may include a first electrode part PO3, and a second electrode part PO4 spaced apart from the first electrode part PO3. The first electrode part PO3 of the common electrode CA may be located on the first light-emitting part PO1 of the organic material layer EL. The second electrode part PO4 of the common electrode CA may be located on the second light-emitting part PO2 of the organic material layer EL, and may contact the partition wall SW. That is, the common electrode CA may directly contact the partition wall SW in the display area DA.

A side surface of the common electrode CA may be electrically connected to the entire panel by contacting the partition wall SW. That is, when a panel-driving voltage is applied to the partition wall SW, the organic material layer EL may receive the panel-driving voltage through the common electrode CA in contact with the side surface of the partition wall SW.

The common electrode CA may include a transparent conductive material. For example, the common electrode CA may include lithium (Li), calcium (Ca), aluminum (AI), silver (Ag), magnesium (Mg), barium (Ba), or the like. These may be used alone or in combination with each other.

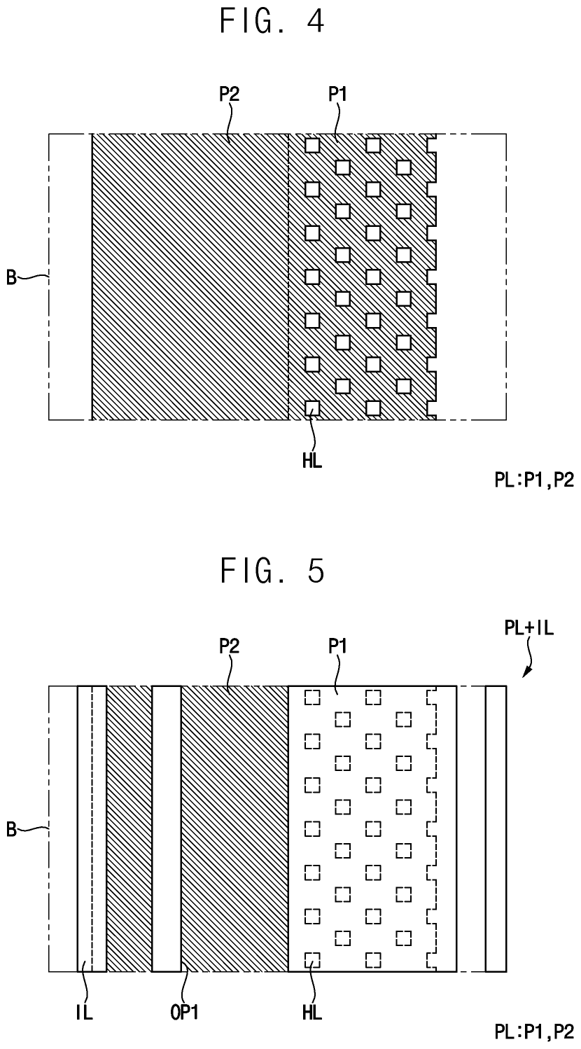

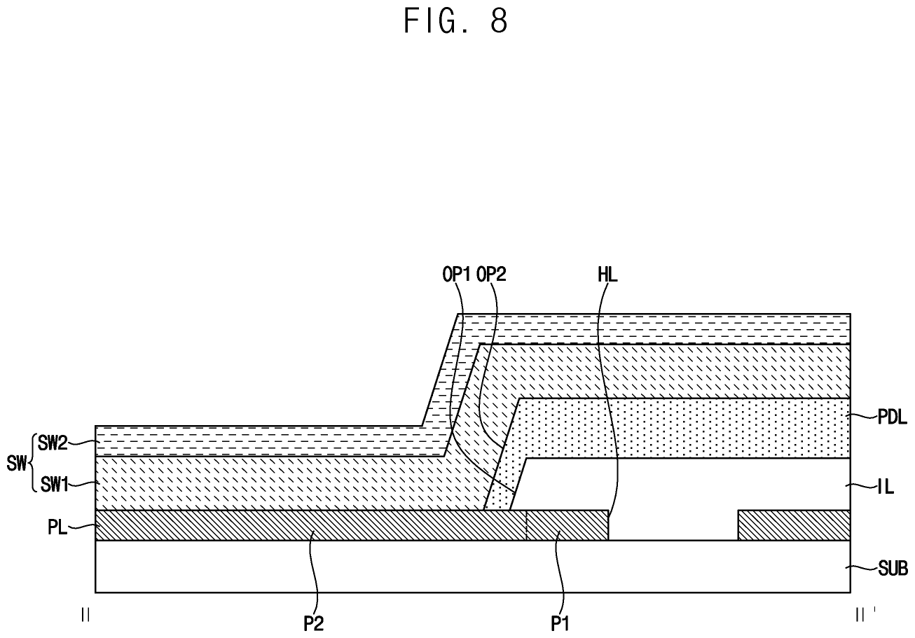

FIGS. 4, 5, 6, and 7 are layout views illustrating parts of a display device according to one or more embodiments of the present disclosure. FIG. 8 is a cross-sectional view taken along the line II-II′ of FIG. 7.

For example, FIGS. 4, 5, 6, and 7 may be layout views of area A of FIG. 1.

Referring to FIGS. 4 and 8, the power line PL may be located on the substrate SUB. The power line PL may transfer the panel-driving voltage to the display area DA. The power line PL may overlap the peripheral area PA, and may not overlap the display area DA. In addition, the power line PL may be located on the same layer as the conductive layer CL. That is, the power line PL may include the same material as the conductive layer CL.

The power line PL may include a first part P1, and a second part P2 adjacent to the first part P1. A plurality of holes HL may be defined in the first part P1, and the plurality of holes HL may not be defined in the second part P2. A gas generated from an organic material may be discharged through the plurality of holes HL. Further referring to FIG. 5, the insulating layer IL may be located on the power line PL. The insulating layer IL may entirely overlap the first part P1, and may partially overlap the second part P2. The insulating layer IL may define a first opening OP1 partially overlapping the power line PL in the peripheral area PA. For example, the first opening OP1 may overlap the second part P2. That is, the first opening OP1 may expose at least a part of the second part P2.

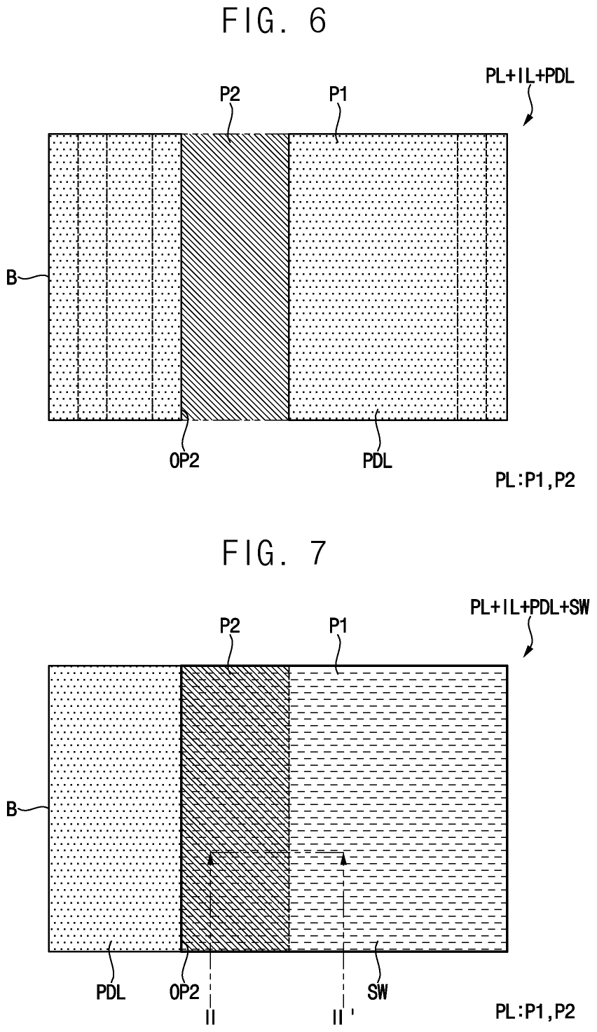

Further referring to FIG. 6, the pixel-defining layer PDL may be located on the insulating layer IL. The pixel-defining layer PDL may entirely overlap the first part P1, and may partially overlap the second part P2. The pixel-defining layer PDL may define a second opening OP2 overlapping the first opening OP1. For example, the second opening OP2 and the first opening OP1 may form one opening. Accordingly, the second opening OP2 may overlap the second part P2, and may expose at least a part of the second part P2.

Referring to FIG. 7, the partition wall SW may be located on the power line PL, the insulating layer IL, and the pixel-defining layer PDL. The partition wall SW may overlap the display area DA and the peripheral area PA. That is, the partition wall SW may extend from the display area DA to the peripheral area PA. In one or more embodiments, the partition wall SW may define a plurality of holes. Gas generated from the organic material may be discharged through the plurality of holes. However, the present disclosure is not limited thereto.

In one or more embodiments, the pixel electrode PXL located in the display area DA may be spaced apart from the power line PL. Therefore, because the pixel electrode PXL is not located between the partition wall SW and the power line PL, the partition wall SW may directly contact the power line PL.

For example, the partition wall SW may overlap the first opening OP1 and the second opening OP2. That is, the partition wall SW may directly contact the second part P2 through the first opening OP1 and the second opening OP2. Accordingly, the first part P1 of the power line PL may overlap the pixel-defining layer PDL and the insulating layer IL, and the second part P2 of the power line PL may directly contact the partition wall SW.

In one or more embodiments, because the pixel electrode PXL is spaced apart from the power line PL, the power line PL and the partition wall SW may directly contact each other. Accordingly, resistance can be reduced because the partition wall SW directly contacts the power line PL in the peripheral area PA, and directly contacts the common electrode CA in the display area DA. In addition, because the pixel electrode PXL is not located between the power line PL and the partition wall SW, an amount of outgassing and a parasitic capacitance can be reduced. Accordingly, reliability of the display device 10 can be improved.

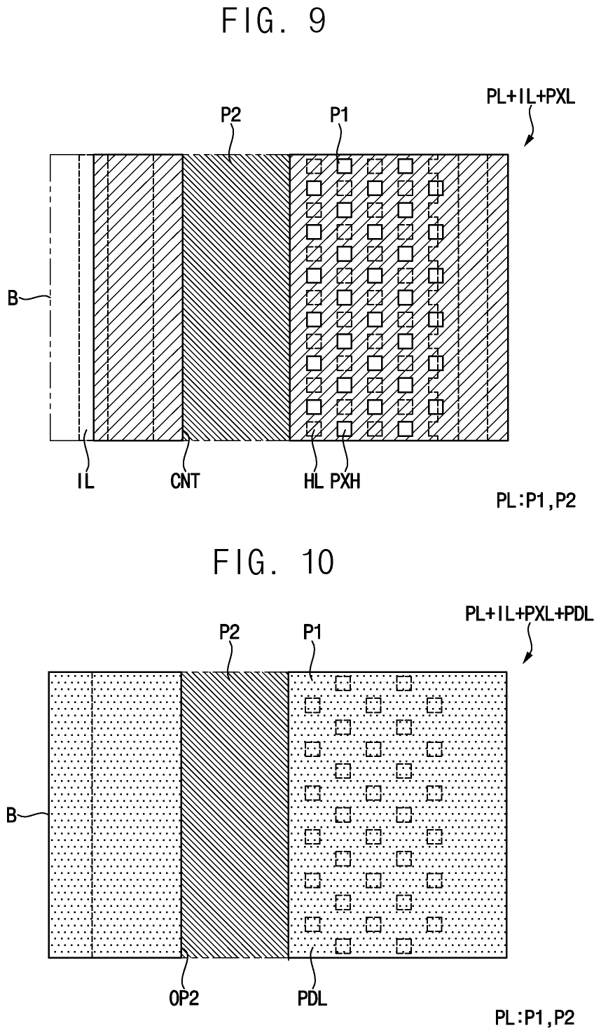

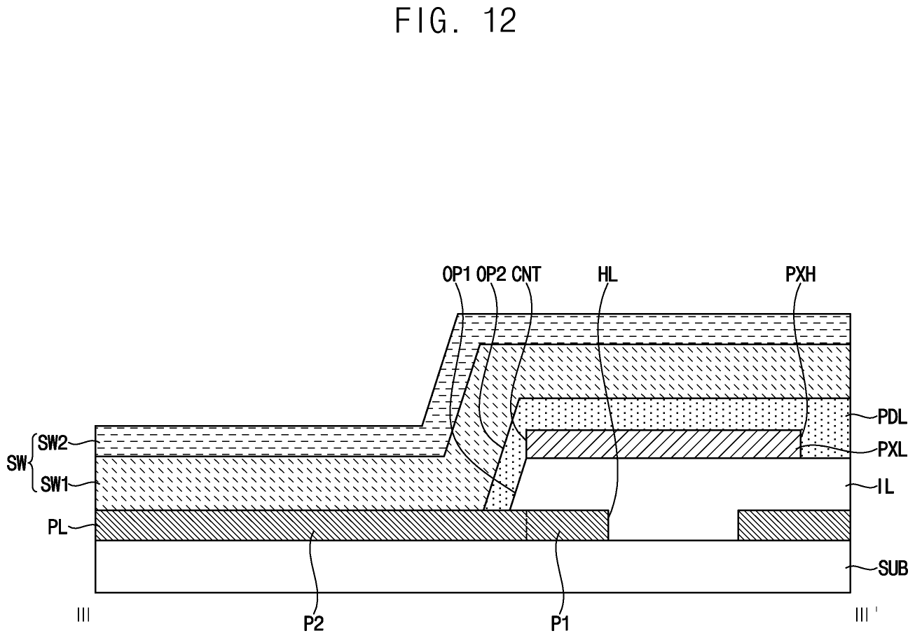

FIGS. 9, 10, and 11 are layout views illustrating a part of a display device according to one or more other embodiments of the present disclosure. FIG. 12 is a cross-sectional view taken along the line III-III′ of FIG. 11.

For example, FIGS. 9, 10, and 11 may be layout views of area A of FIG. 1. In addition, the display device described with reference to FIGS. 9, 10, 11, and 12 may be the same as the display device 10 described with reference to FIGS. 1, 2, 3, 4, 5, 6, 7, and 8 except for the pixel electrode PXL. Accordingly, redundant descriptions may be omitted or simplified.

Referring to FIGS. 4, 5, 9, and 12, the power line PL may be located on the substrate SUB. The power line PL may overlap the peripheral area PA and may not overlap the display area DA.

The power line PL may include the first part P1, and the second part P2 adjacent to the first part P1. The plurality of holes HL may be defined in the first part P1, and the plurality of holes HL may not be defined in the second part P2.

The insulating layer IL may be located on the power line PL. The insulating layer IL may entirely overlap the first part P1, and may partially overlap the second part P2. The insulating layer IL may define the first opening OP1 partially overlapping the power line PL in the peripheral area PA. For example, the first opening OP1 may overlap the second part P2. That is, the first opening OP1 may expose at least a part of the second part P2.

In one or more embodiments, the pixel electrode PXL may be located on the insulating layer IL. The pixel electrode PXL may overlap the display area DA and the peripheral area PA. The pixel electrode PXL may define a contact opening CNT overlapping the power line PL. The contact opening CNT may overlap the first opening OP1. That is, the contact opening CNT may expose at least a part of the second part P2 together with the first opening OP1.

The pixel electrode PXL may define a plurality of pixel holes PXH. A gas generated from an organic material may be discharged through the plurality of pixel holes PXH. However, the present disclosure is not limited thereto.

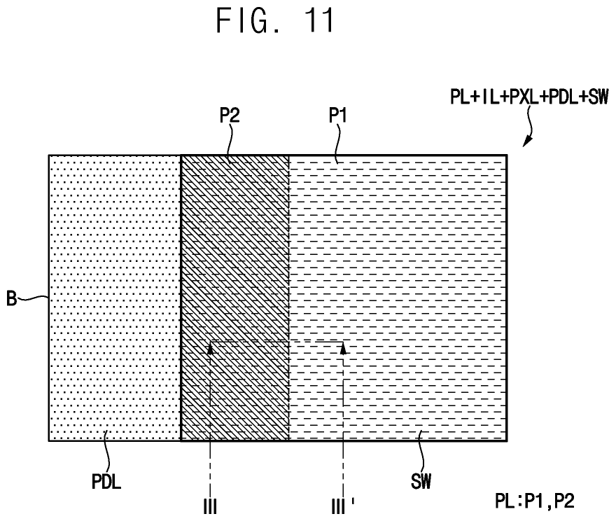

Further referring to FIG. 10, the pixel-defining layer PDL may be located on the insulating layer IL and the pixel electrode PXL. The pixel-defining layer PDL may entirely overlap the first part P1, and may partially overlap the second part P2. The pixel-defining layer PDL may define a second opening OP2 overlapping the first opening OP1 and the contact opening CNT. For example, the second opening OP2 may form one opening with the first opening OP1 and the contact opening CNT. Accordingly, the second opening OP2 may overlap the second part P2, and may expose at least a part of the second part P2.

Further referring to FIG. 11, the partition wall SW may be located on the power line PL, the insulating layer IL, the pixel electrode PXL, and the pixel-defining layer PDL. The partition wall SW may overlap the display area DA and the peripheral area PA. That is, the partition wall SW may extend from the display area DA to the peripheral area PA. In addition, the partition wall SW may contact the common electrode CA in the display area DA.

The partition wall SW may include a first partition layer SW1, and a second partition layer SW2 located on the first partition layer SW1. The first partition layer SW1 and the second partition layer SW2 may include different materials, respectively. For example, the first partition layer SW1 may include aluminum, and the second partition layer SW2 may include titanium.

In one or more embodiments, the partition wall SW may directly contact the power line PL in the peripheral area PA. For example, the partition wall SW may overlap the contact opening CNT, the first opening OP1, and the second opening OP2. That is, the partition wall SW may directly contact the second part P2 through the contact opening CNT, the first opening OP1, and the second opening OP2.

Accordingly, the first part P1 of the power line PL may overlap the pixel electrode PXL, the pixel-defining layer PDL, and the insulating layer IL, and the second part P2 of the power line PL may directly contact the partition wall SW.

In one or more embodiments, because the pixel electrode PXL defines the contact opening CNT overlapping the power line PL and the partition wall SW, the power line PL and the partition wall SW may directly contact through the contact opening CNT. Accordingly, resistance can be reduced because the partition wall SW directly contacts the power line PL in the peripheral area PA, and directly contacts the common electrode CA in the display area DA. Accordingly, reliability of the display device 10 can be improved.

The present disclosure can be applied to various display devices. For example, the present disclosure is applicable to various display devices, such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and aspects of the present disclosure. Accordingly, all such modifications are intended to be included within the scope of the present discourse as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a substrate comprising a display area, and a peripheral area surrounding the display area in plan view;
a power line on the substrate, and overlapping the peripheral area;
a pixel electrode on the substrate, overlapping the display area, and spaced apart from the power line;
a light-emitting layer on the pixel electrode, and overlapping the display area;
a common electrode on the light-emitting layer, and overlapping the display area; and
a partition wall on the substrate, overlapping the display area and the peripheral area, directly contacting the common electrode in the display area, and directly contacting the power line in the peripheral area.

2. The display device of claim 1, wherein the partition wall contacts a side surface of the common electrode.

3. The display device of claim 1, further comprising:
a pixel-defining layer on the substrate, under the partition wall, and exposing a part of the pixel electrode; and
an insulating layer between the substrate and the pixel-defining layer.

4. The display device of claim 3, wherein the insulating layer defines a first opening partially overlapping the power line in the peripheral area, and
wherein the pixel-defining layer defines a second opening overlapping the first opening.

5. The display device of claim 4, wherein the first opening and the second opening overlap the partition wall.

6. The display device of claim 4, wherein the power line comprises:
a first part in which holes are defined, and overlapping the pixel-defining layer and the insulating layer; and
a second part in which the holes are not defined, and directly contacting the partition wall through the first opening and the second opening.

7. The display device of claim 3, wherein the pixel-defining layer comprises an inorganic material.

8. The display device of claim 3, wherein the insulating layer comprises an organic material.

9. The display device of claim 3, wherein the partition wall comprises:
a first partition layer on the pixel-defining layer; and
a second partition layer on the first partition layer.

10. The display device of claim 9, wherein the first partition layer and the second partition layer comprise different respective materials.

11. The display device of claim 10, wherein the first partition layer comprises aluminum, and wherein the second partition layer comprises titanium.

12. The display device of claim 1, wherein the partition wall extends from the display area to the peripheral area.

13. A display device comprising:
a substrate comprising a display area, and a peripheral area surrounding the display area in plan view;
a power line on the substrate, and overlapping the peripheral area;
a pixel electrode on the substrate, overlapping the display area and the peripheral area, and defining a contact opening overlapping the power line;
a light-emitting layer on the pixel electrode, and overlapping the display area;
a common electrode on the light-emitting layer, and overlapping the display area; and
a partition wall on the pixel electrode, overlapping the display area and the peripheral area, directly contacting the common electrode in the display area, and directly contacting the power line through the contact opening in the peripheral area.

14. The display device of claim 13, wherein the partition wall contacts a side surface of the common electrode.

15. The display device of claim 13, further comprising:
a pixel-defining layer on the pixel electrode, under the partition wall, and exposing a part of the pixel electrode in the display area; and
an insulating layer between the substrate and the pixel electrode.

16. The display device of claim 15, wherein the insulating layer defines a first opening overlapping the contact opening, and
wherein the pixel-defining layer defines a second opening overlapping the first opening.

17. The display device of claim 16, wherein the contact opening, the second opening, and the second opening overlap the partition wall.

18. The display device of claim 16, wherein the power line comprises a first part in which holes are defined, and a second part in which the holes are not defined,
wherein the first part overlaps the pixel-defining layer, the pixel electrode, and the insulating layer, and
wherein the second part directly contacts the partition wall through the contact opening, the first opening, and the second opening.

19. The display device of claim 15, wherein the partition wall comprises:
a first partition layer on the pixel-defining layer; and
a second partition layer on the first partition layer, and comprising a material that is different from that of the first partition layer.

20. The display device of claim 19, wherein the first partition layer comprises aluminum, and wherein the second partition layer comprises titanium.
